(19) United States
(12) Patent Application Publication
(10) Pub. No.: US 2004/0179337 A1
(43) Pub. Date: Sep. 16, 2004

(54) Baking system including a cooling apparatus manufactured using a heatpipe

(76) Inventors: Jin-sung Lee, Seoul (KR); Dong-woo Lee, Seoul (KR); Tae-gyu Kim, Hwaseong-gun (KR); Sang-kap Kim, Osan-si (KR); Dong-hwa Shin, Yongin-si (KR)

Correspondence Address: LEE & STERBA, P.C., 1101 WILSON BOULEVARD, SUITE 2000, ARLINGTON, VA, 22209, US

(21) Appl. No.: 10/799,652

(22) Filed: Mar. 15, 2004

(30) Foreign Application Priority Data
Mar. 14, 2003 (KR) 2003-16018

(51) Int. Cl. H05K 7/20

(52) U.S. Cl. 361/700

(57) ABSTRACT

A baking system including a plate for receiving a wafer to be baked, a heater for heating the plate, and a cooling apparatus for cooling the plate, the cooling apparatus including a cooling element for cooling the plate using vaporization of a coolant therein, the cooling element arranged in proximity to the plate with the heater disposed therebetween, a coolant storage tank for supplying the coolant to the cooling element when the plate is cooled and for storing the coolant when the plate is heated, and a thermostatic element for maintaining a temperature of the coolant supplied into the cooling element constant when the plate is cooled.

### BACKGROUND OF THE INVENTION

1 Field of the Invention

The present invention relates to a baking system in a process of manufacturing semiconductor devices. More particularly, the present invention relates to a baking system that includes a cooling apparatus manufactured using a heatpipe.

2. Description of the Related Art

Photolithography, as applied to the manufacture of semiconductor devices, includes coating a wafer with a photoresist film, pre-baking the photoresist film before exposure, and performing a post-exposure baking process to form a predetermined pattern in the photoresist film.

The baking temperature used in the photolithography process depends on a type of photoresist film used and applied processes. For example, baking may be performed at 150° C. or 90° C. For this reason, currently available baking systems are equipped with a heating system and a cooling to control the baking temperature depending on a particular situation.

FIGS. 1 through 3 illustrate sectional views of conventional cooling systems of baking equipment. In a first conventional cooling system as shown in FIG. 1, a heating plate 51 is cooled by circulation of a coolant through coolant paths 56 and 57 formed in a plate 54. The first conventional cooling system additionally includes a heater 52, a lift pin 53, and a cooling plate 55. In coolant supply pipelines 60 and 61, the coolant may either be water or air. The coolant supply pipelines 60 and 61 include switching valves 62 and 63, respectively, and terminate at a drain 64. In the first conventional cooling system, reference numeral 65 denotes a thermal sensor, reference numeral 66 denotes a unit controller, reference numeral 67 denotes a temperature controller, reference numeral 68 denotes a solenoid valve (SOL), reference numeral 69 denotes a power supply, and reference numeral 80 denotes a system controller that controls the operation of the entire system.

In a second conventional cooling system as shown in FIG. 2, a plurality of nozzles 74 are disposed under a heating plate 70, which acts as a baking plate. A spray of a fluid from the nozzles 74 onto the heating plate 70 is used to cool the plate 70. In the second conventional cooling system, reference numeral 71 denotes a heater, reference numeral 83 denotes a guide, reference numeral 85 denotes an internal case, reference numeral 87 denotes a spot ring, reference numeral 93 denotes a cooling plate, and reference numeral 96 denotes a black plate.

A third conventional cooling system as shown in FIG. 3 includes a peltier device 101 in a cooling plate 100. The peltier device 101 controls a temperature of the cooling plate 100 within a predetermined range. The cooling system also includes a power controller 102, which supplies power to the peltier device 101, a temperature controller 103, which controls the temperature of the peltier device 101, and a proportional integral derivative (PID) control parameter altering element 105. There is also a flow path 111 through which heat generated by the peltier device 101 dissipates. In the third conventional cooling system, reference numeral 90 denotes a pin that moves a wafer W up and down, reference numeral 91 denotes a through hole, reference numeral 92 denotes a proximeter pin, and reference numeral 104 denotes a thermal sensor that senses the temperature of the cooling plate 100.

In the above-described conventional cooling systems, although they have some advantages, there are greater temperature variations between regions in the baking plate due to localized cooling. More specifically, the entire baking plate is unevenly cooled. Furthermore, a significant amount of time is required to cool the baking plate to a desired uniform temperature distribution. These disadvantages of the conventional cooling systems greatly lower the productivity of semiconductor devices.

As an alternative to such conventional cooling systems, installing a plurality of baking plates that are set to various temperatures has been suggested. Although a time required for cooling can be reduced by this method, installing a plurality of baking plates within a spinner undesirably enlarges the spinner.

### SUMMARY OF THE INVENTION

In an effort to overcome at least some of the above-described disadvantages, the present invention provides a baking system that includes a cooling apparatus manufactured using a heatpipe. The baking system according to the present invention allows a baking plate installed therein to be evenly heated and cooled over an entire area thereof in a relatively short time.

According to a feature of an embodiment of the present invention, there is provided a baking system including a plate for receiving a wafer to be baked, a heater for heating the plate, and a cooling apparatus for cooling the plate, the cooling apparatus including a cooling element for cooling the plate using vaporization of a coolant therein, the cooling element arranged in proximity to the plate with the heater disposed therebetween, a coolant storage tank for supplying the coolant to the cooling element when the plate is cooled and for storing the coolant when the plate is heated, and a thermostatic element for maintaining a temperature of the coolant supplied into the cooling element constant when the plate is cooled. The coolant may be selected from the group consisting of acetone, methanol, water, and distilled water.

The coolant storage tank may include a coolant flowing element for flowing the coolant into the cooling element when the plate is cooled. The coolant flowing element may be a heater disposed adjacent to the coolant storage tank. Alternatively, the coolant flowing element may be a heater integrated with the coolant storage tank in a single body.

The thermostatic element may include a cooling water storage tank for circulating cooling water through the cooling element and a cooling water supply pipeline, which is a path of the cooling water, that extends into the cooling element and provides flow communication between the cooling element and the cooling water storage tank. The cooling water supply pipeline may include a valve between the cooling water storage tank and the cooling element.

The baking system may further include a coolant supply pipeline for providing flow communication between the coolant storage tank and the cooling element. The coolant supply pipeline may have a valve between the coolant storage tank and the cooling element.

Preferably, the cooling element is a heatpipe having a ceiling portion and internal side portions.

The heatpipe may include a wick on the ceiling portion and internal side portions of the heatpipe. Alternatively, the baking system may include a wick plate having a plurality of planar wicks installed on the ceiling portion of the heatpipe and a wick formed on the internal side portions of the heatpipe to guide the coolant to flow toward the wick plate. In another alternate arrangement, the baking system may further include a wick plate installed on the ceiling portion and internal side portions of the heatpipe.

According to the present invention, the entire baking plate can be evenly heated and cooled in a relatively short period of time, e.g., in tens of seconds.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIGS. 1 through 3 illustrate sectional views of a first through a third conventional cooling system of baking equipment, respectively;

FIG. 4 illustrates a sectional view of a baking system including a cooling system manufactured using a heatpipe according to an embodiment of the present invention;

FIGS. 5 and 6 illustrate sectional views of the baking system of FIG. 4 in a heating mode and a cooling mode, respectively;

FIG. 7 is a graph illustrating results of a simulation test for measuring cooling efficiency using the baking system according to the present invention, which includes the heatpipe-installed cooling system;

FIGS. 8 and 9 are graphs illustrating results of a simulation test for measuring cooling efficiency using a conventional baking system as a control and a natural cooling type baking system, respectively; and

FIGS. 10 and 11 illustrate front and plan views of the conventional baking system used as the control in the simulation test for comparison with the baking system according to the present invention.

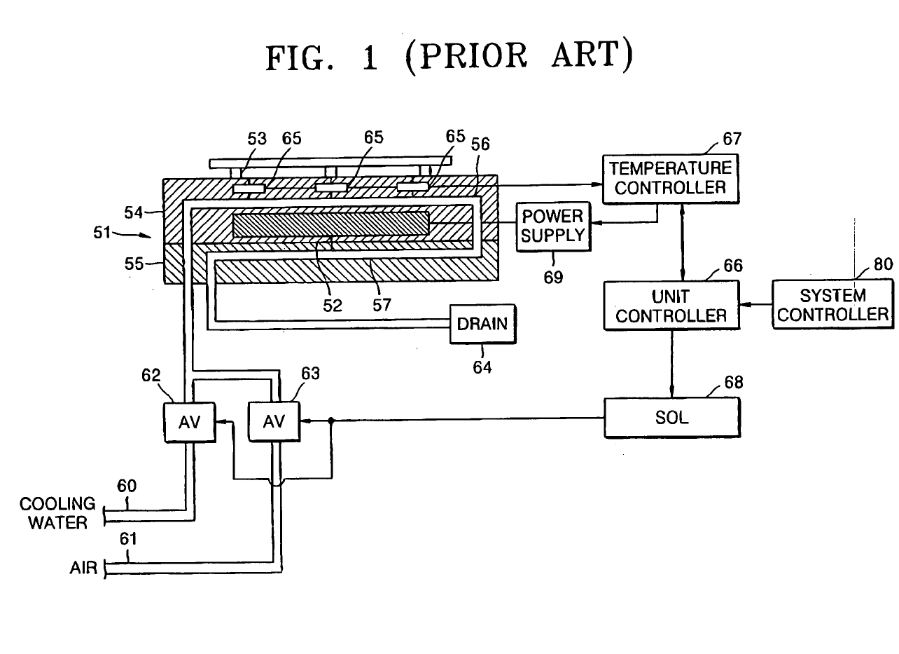

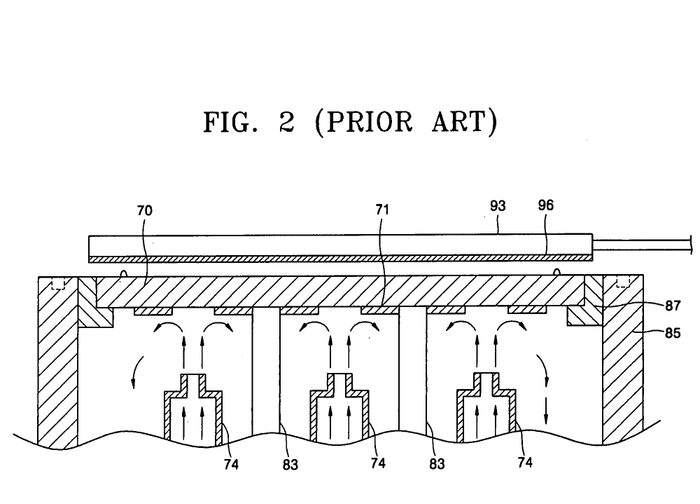

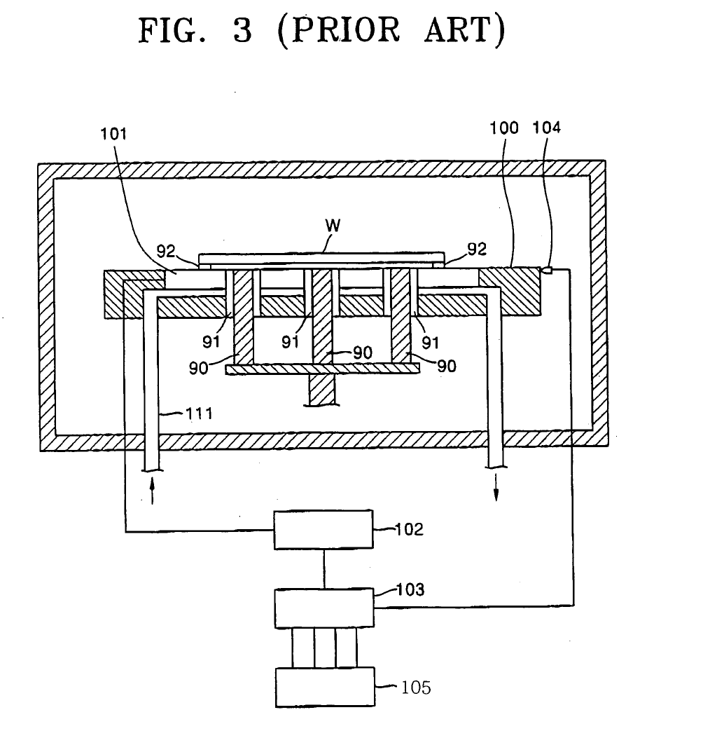

### DETAILED DESCRIPTION OF THE INVENTION

Korean Patent Application No. 2003-16018, filed on Mar. 14, 2003, and entitled: “Baking System Including a Cooling Apparatus Manufactured Using a Heatpipe,” is incorporated by reference herein in its entirety.

The present invention will now be described more fully hereinafter with reference to the accompanying drawings, in which preferred embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration. Like reference numerals refer to like elements throughout.

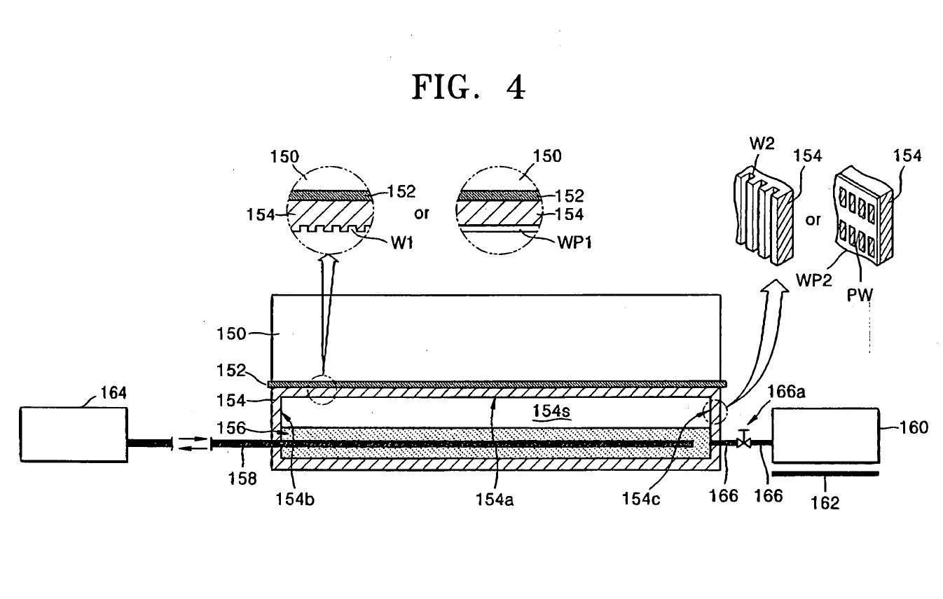

Referring to FIG. 4, a baking system according to an embodiment of the present invention includes a plate 150 for receiving a wafer to be coated with a photoresist film and then baked, a heater 152 for heating the plate 150, and a cooling apparatus. The cooling apparatus includes a cooling element 154, preferably a heatpipe, for cooling the plate 150, a coolant storage tank 160 that stores a coolant and supplies the coolant into the heatpipe 150 depending on a particular situation, and a thermostatic element that maintains the temperature of the coolant supplied to the plate 150 constant when the plate is cooled. The heatpipe 154 uses vaporization of a coolant therein to cool the plate and is arranged in proximity to the plate with the heater disposed therebetween. The thermostatic element includes a cooling water supply pipeline 158 extending through an interior of the heatpipe 154 close to a bottom surface thereof and a cooling water storage tank 164 that supplies a coolant, e.g., water, to the cooling water supply pipeline 158. In addition, the cooling water supply line 158 may include a valve between the cooling water storage tank 164 and the heatpipe 154 to open or close the pipeline. The heater 152, which is attached to a surface of the plate 150, heats the plate 150 to a predetermined baking temperature, for example, 150° C. or 190° C., and maintains the plate 150 at that temperature. The heatpipe 154, which is a heat conductor, is positioned under the heater 152. A phase change of the coolant resulting from heating allows the heatpipe 154 to externally transfer heat generated by the plate 150 during a cooling process. To this end, a first wick W1 may be formed on a ceiling portion 154a of the heatpipe 154 and a second wick W2 may be formed on internal side portions 154b and 154c of the heatpipe 154. The first and second wicks W1 and W2 may have various shapes, e.g., a linear shape, a spiral shape, a radial shape, or the like.

In the alternative to installing only a wick in the heatpipe 154, a first wick plate WP1 having a plurality of planar wicks may be installed on the ceiling portion 154a of the heatpipe 154 and the second wick W2 may be formed on the internal side portions 154b and 154c of the heatpipe 154 to guide the coolant to flow toward the first wick plate WP1. In another alternate arrangement, the first wick plate WP1 may be installed on the ceiling portion 154a and a second wick plate WP2 having a plurality of planar wicks PW may be installed on the internal side portions 154b and 154c of the heatpipe 154.

As a coolant 156 supplied from the coolant storage tank 160 to the heatpipe 154 reaches the internal side portions 154b and 154c, which include the second wick W2 or the second wick plate WP2, of the heatpipe 154, a capillary force is exerted on the coolant 156. Since the second wick W2 or the second wick plate WP2 extends up to the ceiling portion 154a of the heatpipe 154, the coolant 156 spontaneously spreads over the entire ceiling portion 154a of the heatpipe 154 due to the capillary force. The coolant 156 supplied over the ceiling portion 154a of the heatpipe 154 absorbs heat from the plate 150 and undergoes a phase change. More specifically, the coolant 156 vaporizes. Through this process, the heat of the plate 150 externally dissipates and the plate 150 is cooled.

Once the plate 150 has been heated, the temperature of the plate 150 is uniform over a surface of the plate 150 closest to the heatpipe 154 at a time of initiating cooling. More specifically, heat is uniformly transferred from the plate 150 to the heatpipe 154. The coolant 156 is supplied evenly over the ceiling portion 154a of the heatpipe 154 as described above. Accordingly, the coolant 156 vaporizes throughout the ceiling portion 154a of the heatpipe 154. As a result, the entire surface of the plate 154 closest to the heatpipe 154 is cooled more quickly than when using conventional systems. Reference numeral 154s denotes a region where the coolant vaporizes. The vaporized coolant in region 154s descends toward the liquid coolant 156 in a lower region due to a difference in atmospheric pressure with respect to the lower region where the liquid coolant 156 is present and condensates upon contacting the liquid coolant 156.

The coolant storage tank 160, from which the coolant 156 is supplied to the heatpipe 154, is installed outside the heatpipe 154. A coolant supply pipeline 166 provides flow communication between the heatpipe 154 and the coolant storage tank 160. In addition, the coolant supply pipeline 166 may include a valve 166a between the coolant storage tank 160 and the heatpipe 154 to open or close the pipeline.

The internal pressure of the heatpipe 154 rises while the plate 150 is heated, leading to a difference in atmospheric pressure between the heatpipe 154 and the coolant storage tank 160, so that the coolant 156 supplied to the heatpipe 154 to cool the plate 150 moves back into the coolant storage tank 160 and the heatpipe 154 does not operate while the plate 150 is heated.

As a result, heat generated by the heater 152 to heat the plate 150 remains in the plate 150, thereby heating the plate 150 more quickly.

When initiating cooling of the plate 150, the coolant 156, which has moved into the coolant storage tank 160 as the plate 150 was heated, must be allowed to enter the heatpipe 154. However, since the internal pressure of the heatpipe 154 is still higher than the internal pressure of the coolant storage tank 160, the coolant 156 cannot flow naturally from the coolant storage tank 160 to the heatpipe 154 and must be forced to flow into the heatpipe 154.

To provide this forced flow, the coolant storage tank 160 is equipped with a coolant flowing element, preferably an auxiliary heater 162. The auxiliary heater 162, which is a means for causing the coolant 156 to flow from the coolant storage tank 160 into the heatpipe 154, may be located at any position adjacent to the coolant storage tank, e.g., under, above, or on a side of the coolant storage tank 160. In addition, the auxiliary heater 162 may be integrated with the coolant storage tank 160 in a single body. As the coolant storage tank 160 is heated by the auxiliary heater 162, the internal pressure of the coolant storage tank 160 rises above the internal pressure of the heatpipe 154, so that the coolant 156 in the coolant storage tank 160 is allowed to enter the heatpipe 154 to a level such that the cooling water supply pipeline 158 is submerged in the coolant 156. The coolant 156 may be acetone, methanol, water, distilled water, or the like.

The cooling water storage tank 164, from which cooling water is supplied to the cooling water supply pipeline 158, is located outside the heatpipe 154. The cooling water supply pipeline 158 provides flow communication between the cooling water storage tank and the heatpipe 154. Although the cooling water supply pipeline 158 in FIG. 4 is illustrated as a single pipeline, the cooling water supply pipeline is actually comprised of two pipelines. One of the two pipelines supplies cooling water from the cooling water storage tank 164 to the heatpipe 154, and the other pipeline discharges the cooling water.

Supplying the cooling water from the cooling water storage tank 164 to the heatpipe 154 is initiated after a wafer (not shown) loaded on the plate 150 is baked. Supplying the cooling water to the heatpipe 154 may be performed simultaneously with supplying the coolant 156 to the heatpipe 154. However, supplying the cooling water through the cooling water supply pipeline 158 to the heatpipe 154 is sufficient to cool the heated atmosphere in the heatpipe 154. Accordingly, supplying the cooling water may precede supplying the coolant 156. Alternatively, supplying the coolant 156 may precede supplying the cooling water. In this case, since the heat of the plate 150 is transferred to the coolant to vaporize it and raise a temperature of the coolant, it is preferable that the cooling water is supplied as soon as possible after the coolant 156 is supplied.

In addition, since the temperature of the coolant 156 rises when cooling the plate 150, as described above, a temperature of the cooling water supplied through the cooling water supply pipeline 158 should be maintained low enough to cool the coolant 156, for example, at 18° C. Heat transferred from the plate 150 to the coolant 156 is absorbed by the cooling water and dissipates out of the heatpipe 154. As a result, the temperature of the coolant 156 is maintained low enough to condensate the vaporized coolant near the ceiling portion 154a of the heatpipe 154.

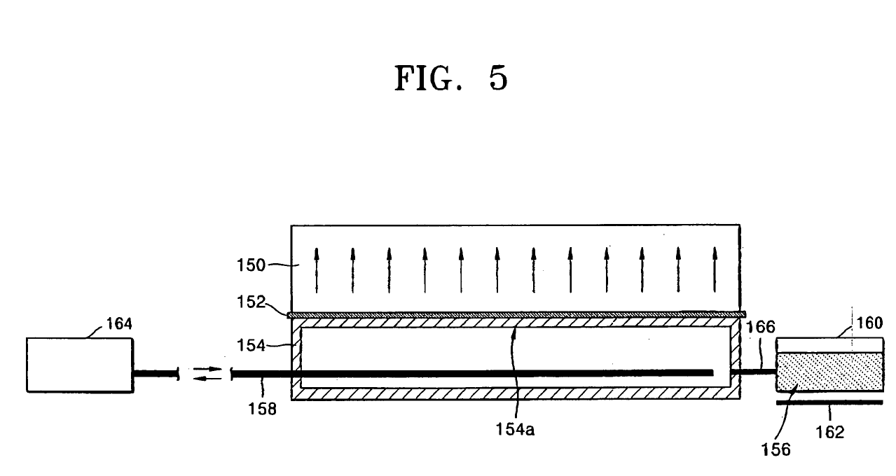

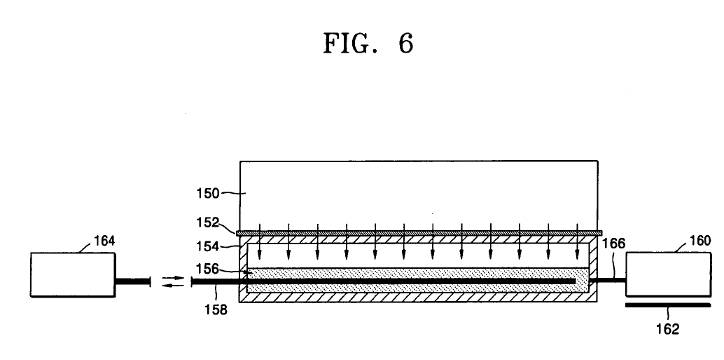

FIGS. 5 and 6 illustrate sectional views for explaining an operation of the baking system according to the embodiment of the present invention described above in a heating mode and a cooling mode, respectively. In FIGS. 5 and 6, arrows indicate directions in which heat is transferred.

Referring to FIGS. 4 and 5, the coolant 156, which was supplied to the heatpipe 154 for cooling, moves through the coolant supply pipeline 166 into the coolant storage tank 160 when the plate 150 is to be heated. As a result, heat generated by the heater 152 remains in the plate 150.

Referring to FIG. 6, as the auxiliary heater 162 is operated to heat the coolant storage tank 160, the coolant 156 in the coolant storage tank 160 flows into the heatpipe 154. The coolant 156 quickly spreads over the ceiling portion 154a of the heatpipe 154 due to the wick, which was described above as being embedded in the heatpipe 154, thereby allowing uniform heat transfer from the entire plate 150 to the heatpipe 154 and allowing the plate 150 to be evenly cooled.

The performance of the baking system according to the present invention will now be demonstrated with reference to a simulation test and results thereof.

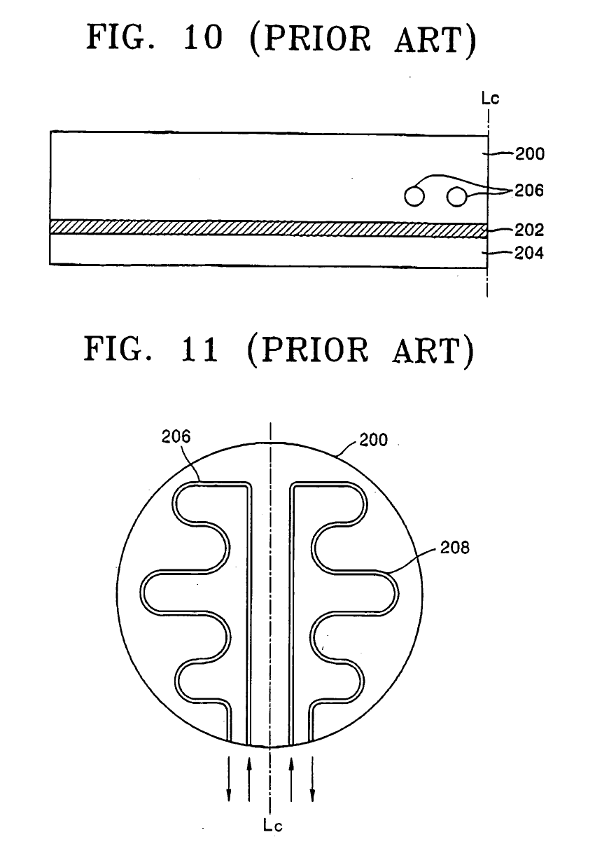

In the simulation test, a conventional baking system as illustrated in FIGS. 10 and 11 was utilized as a control. Referring to FIGS. 10 and 11, reference numeral 200 denotes a plate in which first and second cooling water supply pipelines 206 and 208 are embedded, reference numeral 202 denotes a mica layer, and reference numeral 204 denotes a heater. Reference character Lc denotes a line that bisects the plate 200 in FIG. 11. FIG. 10 is a front view of the plate 200 illustrating only a left half thereof as divided along line Lc.

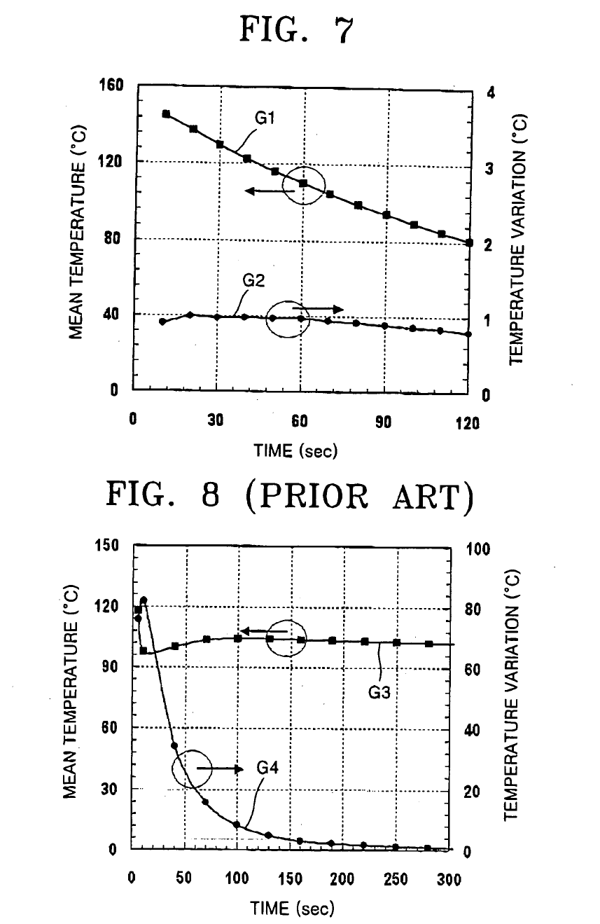

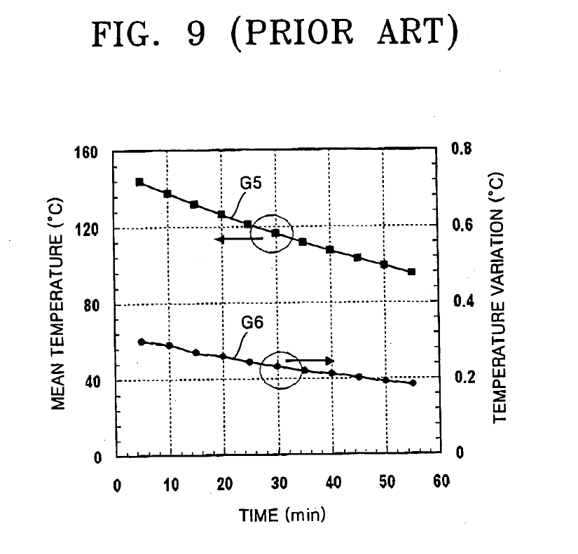

FIGS. 7 through 9 are graphs illustrating results of the simulation test performed on the baking system according to the present invention and the conventional baking system. In particular, FIG. 7 is a graph illustrating a mean temperature and a temperature variation at an upper surface of the plate with respect to time when the plate is cooled using the baking system according to the present invention. FIG. 8 is a graph illustrating a mean temperature and a temperature variation at an upper surface of the plate with respect to time when the plate is cooled using the conventional baking system. FIG. 9 is a graph illustrating a mean temperature and a temperature variation at an upper surface of the plate with respect to time when, contrary to the baking system according to the present invention or the conventional baking system, no intentional cooling is performed.

In FIGS. 7 through 9, plots G1, G3, and G5 indicate variations in the mean temperature of the plate when using the different baking systems, and plots G2, G4, and G6 indicate variations in the temperature variation of the plate.

Comparing plots G2, G4, and G6, the temperature variation in the plate 150 in the baking system according to the present invention (G2) ranges from 0.8° C. to 1.0° C., whereas the temperature variation in the plate 200 in the conventional baking system (G4) fluctuates more than in the baking system according to the present invention, in a range from 70° C. to 80° C., even at an early stage of cooling.

When using the natural cooling type baking system, there is a minor temperature variation of 0.2-0.3° C., as indicated by a plot G6, which is much smaller than in the baking system according to the present invention and the conventional baking system. However, the natural cooling type baking system requires a substantially longer time for cooling and stabilization, which will be described later, than the baking system according to the present invention or the conventional baking system.

Comparing plots G1, G3, and G5, it takes about 80 seconds to cool the baking plate 150 from 150° C. to 100° C. and stabilize it in the baking system according to the present invention. However, it takes about five minutes for the conventional baking system and about 50 minutes for the natural cooling type baking system to cool and stabilize the baking plate to the same temperature.

The durations of time required to cool and stabilize the cooling plates in the three different baking systems are tabled below.

| | Present | Conventional | Natural Cooling |
|---|---|---|---|
| Type of System | Invention | System | Type System |
| Time required to | 80 seconds | 5 minutes | 50 minutes |
| cool from 150° C. | | | |
| to 100° C. | | | |

As described above, although temperature variation is smallest in the natural cooling type baking system, the natural cooling type baking system has no practical applications because it requires too long of a duration of time to cool and stabilize, as compared to the baking system according to the present invention or the conventional baking system.

From the above simulation analysis results, it may be seen that the baking system according to the present invention has a relatively small temperature variation, which is similar to the natural cooling type baking system, and requires a relatively short time to cool and stabilize as compared to the other tested conventional baking systems.

As described above, a baking system according to an embodiment of the present invention includes a heatpipe as a cooling apparatus disposed below a baking plate and a heater. The heatpipe may include a wick in a ceiling portion and inner side portions thereof and is filled with a coolant when cooling such that the wick, if present, is submerged. A cooling water supply pipeline connected to an external cooling water storage tank is positioned near an internal bottom surface of the heatpipe. As a result, the coolant can be rapidly and uniformly supplied over the ceiling portion of the heatpipe in proximity to the baking plate when cooling, thereby allowing the entire baking plate to be evenly cooled. In addition, the baking plate is additionally cooled by the vaporization of the coolant near the ceiling portion of the heatpipe, so that the time required for cooling is significantly reduced as compared to conventional cooling systems that exclusively use circulation of cooling water.

Preferred embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A baking system including a plate for receiving a wafer to be baked, a heater for heating the plate, and a cooling apparatus for cooling the plate, the cooling apparatus comprising:
a cooling element for cooling the plate using vaporization of a coolant therein, the cooling element arranged in proximity to the plate with the heater disposed therebetween;
a coolant storage tank for supplying the coolant to the cooling element when the plate is cooled and for storing the coolant when the plate is heated; and
a thermostatic element for maintaining a temperature of the coolant supplied into the cooling element constant when the plate is cooled.

2. The baking system as claimed in claim 1, wherein the coolant storage tank comprises a coolant flowing element for flowing the coolant into the cooling element when the plate is cooled.

3. The baking system as claimed in claim 1, wherein the thermostatic element comprises:
a cooling water storage tank for circulating cooling water through the cooling element; and
a cooling water supply pipeline, which is a path of the cooling water, that extends into the cooling element and provides flow communication between the cooling element and the cooling water storage tank.

4. The baking system as claimed in claim 3, wherein the cooling water supply pipeline has a valve between the cooling water storage tank and the cooling element.

5. The baking system as claimed in claim 1, further comprising a coolant supply pipeline for providing flow communication between the coolant storage tank and the cooling element.

6. The baking system as claimed in claim 5, wherein the coolant supply pipeline has a valve between the coolant storage tank and the cooling element.

7. The baking system as claimed in claim 1, wherein the cooling element is a heatpipe having a ceiling portion and internal side portions.

8. The baking system as claimed in claim 2, wherein the cooling element is a heatpipe having a ceiling portion and internal side portions.

9. The baking system as claimed in claim 3, wherein the cooling element is a heatpipe having a ceiling portion and internal side portions.

10. The baking system as claimed in claim 2, wherein the coolant flowing element is a heater disposed adjacent to the coolant storage tank.

11. The baking system as claimed in claim 2, wherein the coolant flowing element is a heater integrated with the coolant storage tank in a single body.

12. The baking system as claimed in claim 7, wherein the heatpipe comprises a wick on the ceiling portion and internal side portions of the heatpipe.

13. The baking system as claimed in claim 8, wherein the heatpipe comprises a wick on the ceiling portion and internal side portions of the heatpipe.

14. The baking system as claimed in claim 9, wherein the heatpipe comprises a wick on the ceiling portion and internal side portions of the heatpipe.

15. The baking system as claimed in claim 7, further comprising:
a wick plate having a plurality of planar wicks installed on the ceiling portion of the heatpipe; and
a wick formed on the internal side portions of the heatpipe to guide the coolant to flow toward the wick plate.

16. The baking system as claimed in claim 8, further comprising:
a wick plate having a plurality of planar wicks installed on the ceiling portion of the heatpipe; and
a wick formed on the internal side portions of the heatpipe to guide the coolant to flow toward the wick plate.

17. The baking system as claimed in claim 9, further comprising:
a wick plate having a plurality of planar wicks installed on the ceiling portion of the heatpipe; and
a wick formed on the internal side portions of the heatpipe to guide the coolant to flow toward the wick plate.

18. The baking system as claimed in claim 7, further comprising a wick plate installed on the ceiling portion and internal side portions of the heatpipe.

19. The baking system as claimed in claim 8, further comprising a wick plate installed on the ceiling portion and internal side portions of the heatpipe.

20. The baking system as claimed in claim 9, further comprising a wick plate installed on the ceiling portion and internal side portions of the heatpipe.

21. The baking system as claimed in claim 1, wherein the coolant is selected from the group consisting of acetone, methanol, water, and distilled water.
